(19) United States
(12) Patent Application Publication
(10) Pub. No.: US 2025/0098380 A1
(43) Pub. Date: Mar. 20, 2025

(54) DISPLAY DEVICE, MANUFACTURING METHOD THEREOF, AND AUTOMOTIVE DISPLAY INCLUDING DISPLAY DEVICE

(71) Applicant: Samsung Display Co., LTD., Yongin-si (KR)

(72) Inventors: Rang Kyun MOK, Yongin-si (KR); Young Sang HA, Yongin-si (KR)

(73) Assignee: Samsung Display Co., LTD., Yongin-si (KR)

(21) Appl. No.: 18/771,375

(22) Filed: Jul. 12, 2024

(30) Foreign Application Priority Data
Sep. 19, 2023 (KR) 10-2023-0124877

(51) Int. Cl. H01L 33/58; B60K 35/22; H01L 25/075; H01L 33/50; H01L 33/54

(52) U.S. Cl. CPC H10H 20/855; B60K 35/22; H01L 25/0753; H10H 20/8514; H10H 20/853; H10H 20/0361; H10H 20/0363

(57) ABSTRACT

A display device includes a display panel including light emitting elements and an encapsulation layer overlapping the light emitting elements, a first structure layer disposed on the encapsulation layer, the first structure layer primarily controlling a path of light emitted from the light emitting elements, a second structure layer disposed on the first structure layer, the second structure layer secondarily controlling the path of the light passing through the first structure layer, and a color filter layer disposed on the second structure layer.

### CROSS-REFERENCE TO RELATED APPLICATION(S)

This application claims priority to and the benefit of Korean Patent Application No. 10-2023-0124877 under 35 U.S.C. § 119, filed on Sep. 19, 2023, in the Korean Intellectual Property Office (KIPO), the entire content of which are incorporated herein by reference.

### BACKGROUND

### 1. Technical Field

The disclosure generally relates to a display device and a manufacturing method of the display device, and an automotive display including the display device.

### 2. Description of Related Art

With the development of information technologies, the importance of a display device which is a connection medium between a user and information increases. Accordingly, display devices such as a liquid crystal display device and an organic light emitting display device are increasingly used.

### SUMMARY

Embodiments provide a display device, a manufacturing method of the display device, and an automotive display including the display device, which can control a viewing angle while having desirable visibility. For example, the display device may control a viewing angle without deteriorating visibility.

The technical objectives to be achieved by the disclosure are not limited to those described herein, and other technical objectives that are not mentioned herein would be clearly understood by a person skilled in the art from the description of the disclosure.

In accordance with an aspect of the disclosure, there is provided a display device including a display panel including light emitting elements and an encapsulation layer overlapping the light emitting elements, a first structure layer disposed on the encapsulation layer, the first structure layer primarily controlling a path of light emitted from the light emitting elements, a second structure layer disposed on the first structure layer, the second structure layer secondarily controlling the path of the light passing through the first structure layer, and a color filter layer disposed on the second structure layer.

The first structure layer may include a first pattern layer allowing the light to be transmitted through the first pattern layer, and a second pattern layer alternately disposed with the first pattern layer, the second pattern layer absorbing at least a portion of the light.

The first pattern layer may include a transparent organic material.

The second pattern layer may include at least one of a metal and a metal oxide.

The second pattern layer may decrease a viewing angle of the light emitted from the light emitting elements.

The first pattern layer and the second pattern layer may have a same thickness.

The second pattern layer may have a thickness in a range of about 50 μm to about 100 μm.

The first pattern layer and the second pattern layer may have a single-layer structure.

The first pattern layer and the second pattern layer may have a multi-layer structure with two or more stages.

The second structure layer may include a first electrode disposed on the first structure layer, a switching layer disposed on the first electrode, and a second electrode disposed on the switching layer.

The switching layer may include a scattering particle in which a first state and a second state are electrically switchable, and the second state may have a scattering degree lower than a scattering degree of the first state.

In case that a voltage is not applied to the first electrode and the second electrode, the scattering particle may maintain the first state.

In case that a voltage is applied to the first electrode and the second electrode, the scattering particle may maintain the second state.

In case that the scattering particle is in the first state, the switching layer may increase a viewing angle of the light passing through the first structure layer.

In case that the scattering particle is in the second state, the switching layer may decrease a viewing angle of the light passing through the first structure layer.

In accordance with another aspect of the disclosure, there is provided a method of manufacturing a display device, the method including preparing a display panel including light emitting elements and an encapsulation layer overlapping the light emitting elements, forming a first structure layer on the encapsulation layer, forming a second structure layer on the first structure layer, and forming a color filter layer on the second structure layer.

The forming of the first structure layer may include forming first pattern layers spaced apart from each other on the encapsulation layer, forming a second pattern layer overlapping the first pattern layers and the encapsulation layer, etching the second pattern layer except portions in contact with side surfaces of the first pattern layers, and forming the first pattern layers between the second pattern layers.

The first pattern layers and the second pattern layer may be formed in a single-layer structure or a multi-layer structure with two or more stages.

The second pattern layer may be formed with a thickness in a range of about 50 μm to about 100 μm.

In accordance with still another aspect of the disclosure, there is provided an automotive display including the above-described display device.

### BRIEF DESCRIPTION OF THE DRAWINGS

The above and other features of the disclosure will become more apparent by describing in further detail embodiments thereof with reference to the accompanying drawings, in which:

FIG. 1 is a schematic block diagram illustrating a display device in accordance with an embodiment of the disclosure.

FIG. 2 is a schematic sectional view illustrating a display device in accordance with an embodiment of the disclosure.

FIG. 3 is a schematic view illustrating a first structure layer in accordance with an embodiment of the disclosure.

FIGS. 4 and 5 are schematic views illustrating a second structure layer in accordance with an embodiment of the disclosure.

FIGS. 6 to 9 are schematic views illustrating a manufacturing process of the first structure layer in accordance with an embodiment of the disclosure.

FIGS. 10 to 13 are schematic views illustrating a manufacturing process of the first structure layer in accordance with another embodiment of the disclosure.

FIG. 14 illustrates an example of an electronic device including a display device in accordance with embodiments of the disclosure.

### DETAILED DESCRIPTION OF THE EMBODIMENTS

Hereinafter, embodiments of the disclosure will be described in more detail with reference to the accompanying drawings. In the description below, only a necessary part to understand an operation according to the disclosure is described and the descriptions of other parts are omitted in order not to unnecessarily obscure subject matters of the disclosure. In addition, the disclosure is not limited to embodiments described herein, but may be embodied in various different forms. Rather, embodiments described herein are provided to more thoroughly and completely describe the disclosed contents and to sufficiently transfer the ideas of the disclosure to a person of ordinary skill in the art.

In the entire specification, when an element is referred to as being “connected” or “coupled” to another element, it can be directly connected or coupled to the another element or be indirectly connected or coupled to the another element with one or more intervening elements interposed therebetween. The technical terms used herein are used only for the purpose of illustrating a specific embodiment and not intended to limit the embodiment. It will be understood that when a component “includes,” “comprises” or “has” an element, unless there is another opposite description thereto, it should be understood that the component does not exclude another element but may further include another element. It will be understood that for the purposes of this disclosure, “at least one of X, Y, and Z” can be construed as X only, Y only, Z only, or any combination of two or more items X, Y, and Z (e.g., XYZ, XYY, YZ, ZZ). Similarly, for the purposes of this disclosure, “at least one selected from the group consisting of X, Y, and Z” can be construed as X only, Y only, Z only, or any combination of two or more items X, Y, and Z (e.g., XYZ, XYY, YZ, ZZ).

It will be understood that, although the terms “first”, “second,” etc. may be used herein to describe various elements, these elements should not be limited by these terms. These terms are only used to distinguish one element from another element. Thus, a “first” element discussed below could also be termed a “second” element without departing from the teachings of the disclosure.

Spatially relative terms, such as “below,” “above,” and the like, may be used herein for case of description to describe the relationship of one element to another element, as illustrated in the figures. It will be understood that the spatially relative terms, as well as the illustrated configurations, are intended to encompass different orientations of the apparatus in use or operation in addition to the orientations described herein and depicted in the figures. For example, if the apparatus in the figures is turned over, elements described as “below” or “beneath” other elements or features would then be oriented “above” the other elements or features. Thus, the term “above” may encompass both an orientation of above and below. The apparatus may be otherwise oriented (e.g., rotated 90 degrees or at other orientations) and the spatially relative descriptors used herein interpreted accordingly.

The embodiments of the disclosure are described here with reference to schematic diagrams of some embodiments (and an intermediate structure) of the disclosure, so that changes in a shape as shown due to, for example, manufacturing technology and/or a tolerance may be expected. Therefore, the embodiments of the disclosure shall not be limited to the specific shapes of a region shown here, but include shape deviations caused by, for example, the manufacturing technology. The regions shown in the drawings are schematic in nature, and the shapes thereof do not represent the actual shapes of the regions of the device, and do not limit the scope of the disclosure.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, embodiments of the disclosure will be described in detail with reference to the accompanying drawings.

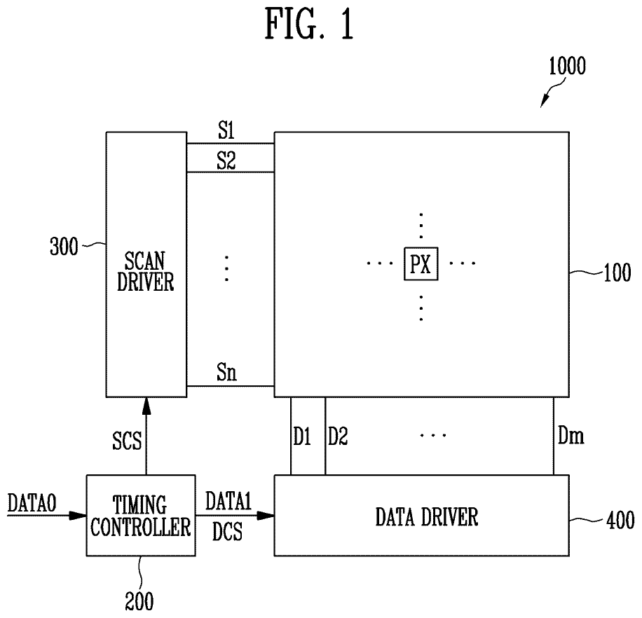

FIG. 1 is a schematic block diagram illustrating a display device in accordance with an embodiment of the disclosure.

Referring to FIG. 1, the display device 1000 may include a display panel 100, a timing controller 200, a scan driver 300, and/or a data driver 400.

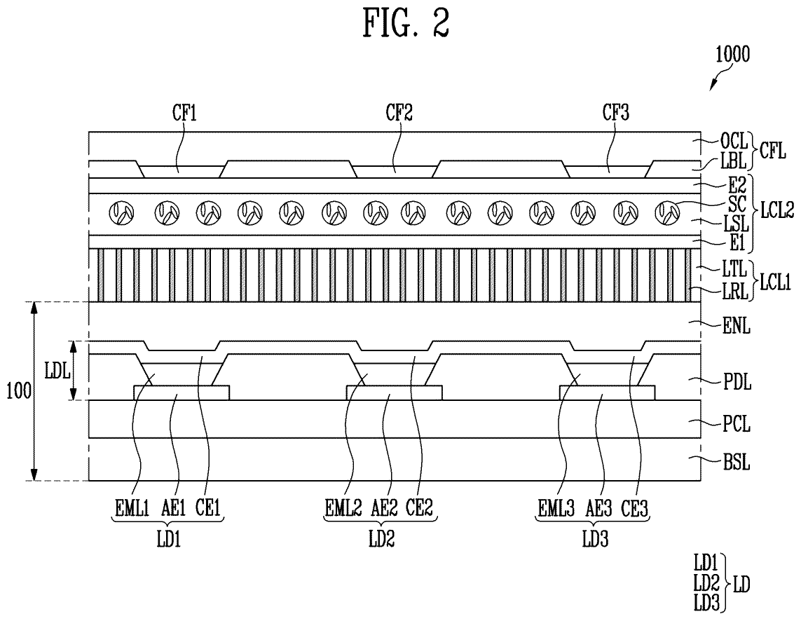

The display device 1000 may be implemented as a light emitting display device including light emitting elements LD (see FIG. 2). For example, the display device 1000 may be an organic light emitting display device including organic light emitting elements, an inorganic light emitting display device including inorganic light emitting elements, or a display device including light emitting elements configured with a combination of an inorganic material and an organic material. However, this is merely illustrative, and the display device 1000 may be implemented, e.g., as a liquid crystal display device, a plasma display device, a quantum dot display device, or the like.

For example, the display device 1000 may be a flat panel display device, a flexible display device, a curved display device, a foldable display device, a bendable display device, a slidable display device, or a three-dimensional display device (e.g., a display device in which an image is displayed not only on a front surface of the display device but also on a side surface and/or a rear surface of the display device).

The display panel 100 may include scan lines S1, S2, . . . , and Sn, data lines D1, D2, . . . , and Dm, and pixels PX. Here, n and m may be natural numbers of 3 or more. The pixels PX may be electrically connected to the data lines D1, D2, . . . , and Dm and the scan lines S1, S2, . . . , and Sn. Pixels PX connected to a scan line S1, S2, . . . , or Sn may be understood as a pixel row. For example, pixels PX connected to a first scan line S1 may be understood as a first pixel row. Pixels PX connected to a data line D1, D2, . . . , or Dm may be understood as a pixel column. For example, pixels PX connected to a first data line D1 may be understood as a first pixel column. Although not shown in the drawing, the pixels PX may be electrically connected to additional emission control lines.

The pixels PX may emit light with a grayscale and a luminance, which correspond to a data signal supplied from the data lines D1, D2, . . . , and Dm. Each of the pixels PX may include a driving transistor and at least one switching transistor. Also, each of the pixels PX may include an organic light emitting element, an inorganic light emitting element, or a light emitting element configured with a combination of an organic material and an inorganic material.

The timing controller 200 may generate a scan control signal SCS and a data control signal DCS, based on clock signals and control signals, which are supplied from the outside. The scan control signal SCS may be supplied to the scan driver 300, and the data control signal DCS may be supplied to the data driver 400. The timing controller 200 may realign input image data DATA0 supplied from the outside and supply the realigned image data DATA1 to the data driver 400.

A scan start pulse and scan clock signals may be included in the scan control signal SCS. The scan start pulse may control a first timing of a scan signal. The scan clock signals may be used to shift the scan start pulse.

A source start pulse and data clock signals may be included in the data control signal DCS. The source start pulse may control a sampling start time of realigned image data DATA1. The data clock signals may be used to control a sampling operation.

The timing controller 200 may realign input image data DATA0, corresponding to an arrangement of the pixels PX, thereby generating image data DATA1. For example, the timing controller 200 may realign the input image data DATA0 as the image data DATA1 having a type in which red, green, and blue are repeated, corresponding to the arrangement of the pixels PX.

The scan driver 300 may supply a scan signal to the scan lines S1, S2, . . . , and Sn corresponding to pixel rows, based on the scan control signal SCS. For example, the scan driver 300 may sequentially supply the scan signal to the scan lines S1, S2, . . . , and Sn. In case that the scan signal is sequentially supplied, the pixels PX may be activated in units of horizontal lines (or units of pixel rows).

The data driver 400 may receive the data control signal DCS and the image data DATA1. The data driver 400 may supply analog data signals obtained by converting the image data DATA1 to the data lines D1, D2, . . . , and Dm, corresponding to the data control signal DCS. The data signals supplied to the data lines D1, D2, . . . , and Dm may be supplied to the pixels PX activated by the scan signal. To this end, the data driver 400 may supply the data signals to the data lines D1, D2, . . . , and Dm to be synchronized with the scan signal.

FIG. 2 is a schematic sectional view illustrating a display device in accordance with an embodiment of the disclosure.

Referring to FIG. 2, the display device 1000 may include a display panel 100, a first structure layer LCL1, a second structure layer LCL2, and/or a color filter layer CFL. The display panel 100 may include a base layer BSL, a pixel circuit layer PCL, a light emitting element layer LDL, and/or an encapsulation layer ENL.

The base layer BSL may constitute a base member, and may include a rigid or flexible substrate or film. For example, the base layer BSL may be a rigid substrate made of glass or tempered glass, a flexible substrate (or thin film) made of plastic or a metal material, or at least one insulating layer. The material and/or property of the base layer BSL are/is not particularly limited. In an embodiment, the base layer BSL may be substantially transparent. The term “substantially transparent” may mean that light can be transmitted with a predetermined transmittance or more. In another embodiment, the base layer BSL may be translucent or opaque. Also, the base layer BSL may include a reflective material.

The pixel circuit layer PCL may be disposed on the base layer BSL. The pixel circuit layer PCL may include a pixel circuit, connection lines, and insulating layers. For example, the pixel circuit layer PCL may include at least one thin film transistor and a storage capacitor. The thin film transistor may include a semiconductor layer including, e.g., amorphous silicon, poly-silicon, or an organic semiconductor material, a gate electrode, a source electrode, and a drain electrode. In order to secure an insulating property of the semiconductor layer and the gate electrode, a gate insulating layer including an inorganic material such as silicon oxide (SiOₓ), silicon nitride (SiNₓ), and/or silicon oxynitride (SiON) may be disposed between the semiconductor layer and the gate electrode. An interlayer insulating layer including an inorganic material such as silicon oxide (SiOₓ), silicon nitride (SiNₓ), and/or silicon oxynitride (SiON) may be disposed over the gate electrode.

The light emitting element layer LDL may be disposed on the pixel circuit layer PCL. The light emitting element layer LDL may include light emitting elements LD and a pixel defining layer PDL.

The light emitting elements LD may include first light emitting elements LD1 emitting light of a first color, second light emitting elements LD2 emitting light of a second color, and third light emitting elements LD3 emitting light of a third color. The first color, the second color, and the third color may be different colors. For example, the first color may be a color among red, green, and blue, the second color may be a color which is not the first color among the red, the green, and the blue, and the third color may be the other color which is not the first color and the second color among the red, the green, and the blue. In another embodiment, magenta, cyan, yellow, and the like may be used as the first to third colors.

Each of the first light emitting elements LD1 may include a first pixel electrode AE1 (or first anode electrode), a first light emitting layer EML1, and a first common electrode CE1 (or first cathode electrode). Each of the second light emitting elements LD2 may include a second pixel electrode AE2 (or second anode electrode), a second light emitting layer EML2, and a second common electrode CE2 (or second cathode electrode). Each of the third light emitting elements LD3 may include a third pixel electrode AE3 (or third anode electrode), a third light emitting layer EML3, and a third common electrode CE3 (or third cathode electrode).

The first to third pixel electrodes AE1 to AE3 may provide holes respectively to the first to third light emitting layers EML1 to EML3. The first to third common electrodes CE1 to CE3 may provide electrons respectively to the first to third light emitting layers EML1 to EML3. The first to third light emitting elements LD1 to LD3 may emit light as excitons generated by recombining holes and electrons in the first to third light emitting layers EML1 to EML3 are changed from an excited state to a ground state.

The pixel defining layer PDL may cover or overlap edges of the first to third pixel electrodes AE1 to AE3. For example, the pixel defining layer PDL may include openings exposing centers of the first to third pixel electrodes AE1 to AE3. Emission areas in which light is emitted may be defined through the openings of the pixel defining layer PDL. The pixel defining layer PDL may include an organic insulating material such as benzocyclobutene, polyimide or hexamethyldisiloxane.

The encapsulation layer ENL may be disposed over the light emitting element layer LDL. For example, the encapsulation layer ENL may be disposed over the light emitting elements LD to cover or overlap the light emitting elements LD. The encapsulation layer ENL may protect the light emitting elements LD from external moisture, heat, impact, and the like. The encapsulation layer ENL may have a multi-layer structure including at least one of an organic encapsulation layer and an inorganic encapsulation layer. The organic encapsulation layer may include an organic insulating material such as acrylic resin, epoxy resin, polyimide or polyethylene. The inorganic encapsulation layer may include an inorganic insulating material such as aluminum oxide, titanium oxide, tantalum oxide, a hafnium oxide, zinc oxide, silicon oxide, silicon nitride, and/or silicon oxynitride.

The first structure layer LCL1 may be disposed on the display panel 100. For example, the first structure layer LCL1 may be disposed on the encapsulation layer ENL of the display panel 100. The first structure layer LCL1 may include a single-layer structure or a multi-layer structure with two or more stages. The first structure layer LCL1 may primarily control a path of light emitted from the light emitting elements LD. The first structure layer LCL1 may include first pattern layers LTL and/or second pattern layers LRL.

The first pattern layers LTL may allow light emitted from the light emitting elements LD to be transmitted therethrough. The first pattern layers LTL may be disposed on the encapsulation layer ENL in a state in which the first pattern layers LTL are spaced apart from each other. Each of the first pattern layers LTL may have a substantially flat top surface. The first pattern layers LTL may include a transparent organic material.

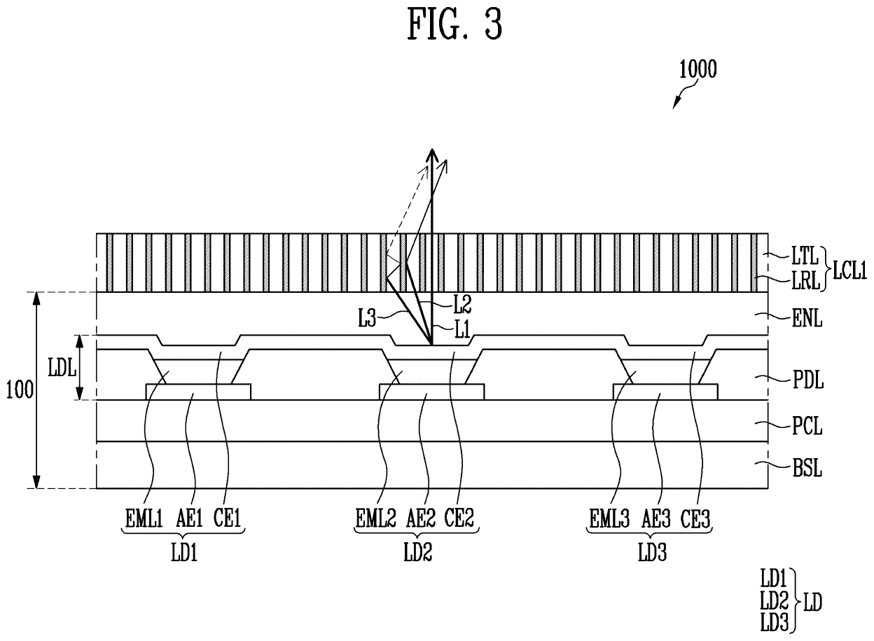

The second pattern layers LRL may absorb or reflect at least a portion of light emitted from the light emitting elements LD. For example, the second pattern layers LRL may decrease the intensity and reflectance of light emitted from the light emitting elements LD. The second pattern layers LRL may be disposed between the first pattern layers LTL. For example, the second pattern layers LRL may be alternately disposed with the first pattern layers LTL on the encapsulation layer ENL. In an embodiment, the second pattern layers LRL may have a thickness in a range of about 50 μm to about 100 μm. In the above range, the second pattern layers LRL can not only efficiently absorb or reflect light but also reduce manufacturing cost and manufacturing processes of the display device 1000. Each of the second pattern layers LRL may have a substantially flat top surface, and the thickness of the second pattern layers LRL may be substantially equal to a thickness of the first pattern layers LTL. A specific function of the second pattern layers LRL will be described below with reference to FIG. 3.

In an embodiment, the second pattern layers LRL may include a metal having a low reflectance. For example, the second pattern layers LRL may include ytterbium (Yb), bismuth (Bi), cobalt (Co), molybdenum (Mo), titanium (Ti), zirconium (Zr), aluminum (Al), chromium (Cr), niobium (Nb), platinum (Pt), tungsten (W), indium (In), tin (Sn), iron (Fc), nickel (Ni), tantalum (Ta), manganese (Mn), zinc (Zn), germanium (Ge), silver (Ag), magnesium (Mg), gold (Au), copper (Cu), calcium (Ca), or any combination thereof. The absorption coefficient of the metal included in the second pattern layers LRL may be about 0.5 or more, but the disclosure is not limited thereto.

In another embodiment, the second pattern layers LRL may include a metal oxide having a low reflectance. For example, the second pattern layers LRL may include silicon oxide (SiO₂), titanium oxide (TiO₂), zirconium oxide (ZrO₂), tantalum pentoxide (Ta₂O₅), hafnium oxide (HfO₂), aluminum oxide (Al₂O₃), zinc oxide (ZnO), yttrium oxide (Y₂O₃), beryllium oxide (BeO), magnesium oxide (MgO), lead oxide (PbO₂), tungsten oxide (WO₃), molybdenum-tantalum oxide (MTO), or any combination thereof.

The second pattern layers LRL may include a combination of the above-described metal and the above-described metal oxide.

The second structure layer LCL2 may be disposed on the first structure layer LCL1. The second structure layer LCL2 may secondarily control the path of the light passing through the first structure layer LCL1. The second structure layer LCL2 may include a first electrode E1, a switching layer LSL, and/or a second electrode E2.

The first electrode E1 may be disposed on the first structure layer LCL1. The second electrode E2 may be disposed to face the first electrode E1. For example, the first electrode E1 and the second electrode E2 may face each other with the switching layer LSL interposed therebetween. The first electrode E1 and the second electrode E2 may include a metal, a metal oxide, a metal nitride, and the like. For example, each of the first electrode E1 and the second electrode E2 may be implemented as a transparent electrode such as indium tin oxide (ITO).

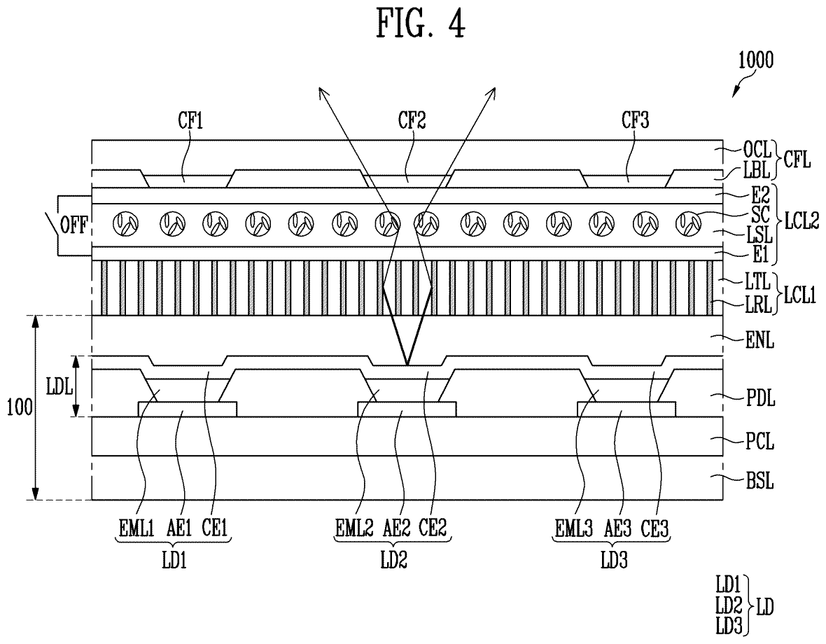

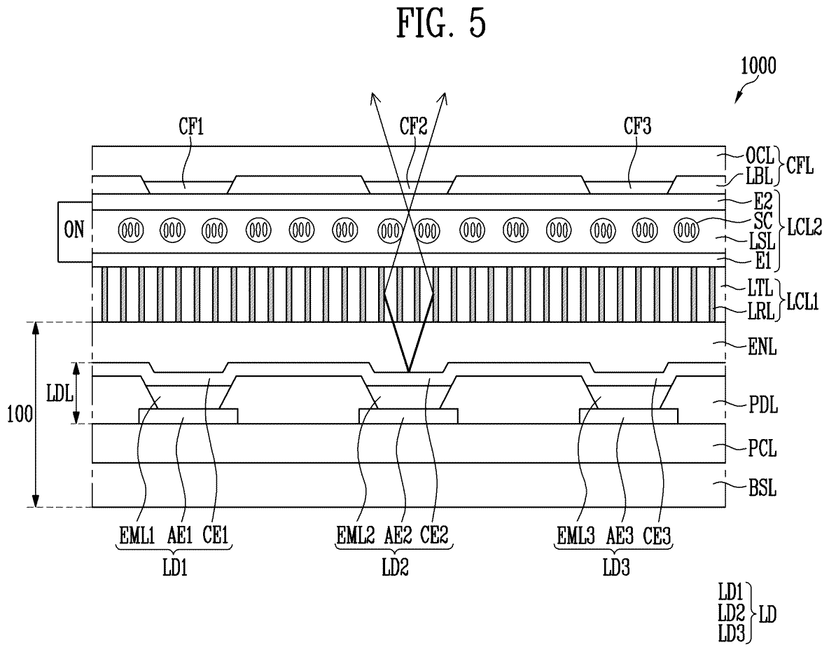

The switching layer LSL may vary a path of light passing through the first structure layer LCL1. In particular, a change degree of the path of light passing through the first structure layer LCL1 may vary according to an optical state of the switching layer LSL. The optical state of the switching layer LSL may be determined according to whether a voltage is applied to the first electrode E1 and the second electrode E2. The switching layer LSL may be disposed on the first electrode E1. Also, the switching layer LSL may be disposed between the first electrode E1 and the second electrode E2. A specific function of the switching layer LSL will be described below with reference to FIGS. 4 and 5.

In an embodiment, the switching layer LSL may include scattering particles SC which are electrically switchable. The term “being electrically switchable” may mean that an optical characteristic is changeable due to a change in molecular arrangement, or the like according to whether a voltage is applied. For example, the scattering degree of the scattering particle SC may vary according to whether a voltage is applied.

In an embodiment, the scattering particle SC may include a liquid crystal molecule such as a reactive mesogen. For example, the scattering particle SC may be a polymer dispersed liquid crystal (PDLC) in which polymer and the liquid crystal molecule are mixed. However, the disclosure is not limited thereto, and any material may be used without limiting the kind thereof as long as the material is electrically switchable.

The color filter layer CFL may be disposed on the second structure layer LCL2. The color filter layer CFL may allow light emitted from the light emitting elements LD1 to LD3 to be selectively transmitted therethrough. The color filter layer CFL may include color filters CF1 to CF3, a light blocking layer LBL, and/or an overcoat layer OCL.

The color filters CF1 to CF3 may be disposed to overlap corresponding light emitting elements LD1 to LD3, respectively. For example, a first color filter CF1 may be disposed to overlap at least a portion of the first light emitting elements LD1. The second color filter CF2 may be disposed to overlap at least a portion of the second light emitting elements LD2. The third color filter CF3 may be disposed to overlap at least a portion of the third light emitting elements LD3.

The color filters CF1 to CF3 may allow lights in different wavelength ranges to be transmitted therethrough. For example, the first color filter CF1 may allow light of a first color, which is emitted from the first light emitting elements LD1, to be transmitted therethrough. The second color filter CF2 may allow light of a second color, which is emitted from the second light emitting elements LD2, to be transmitted therethrough. The third color filter CF3 may allow light of a third color, which is emitted from the third light emitting elements LD3, to be transmitted therethrough.

The color filters CF1 to CF3 may absorb light scattered by the second structure layer LCL2. For example, the first color filter CF1 may absorb light emitted from the second light emitting elements LD2 and/or the third light emitting elements LD3 to be scattered by the second structure layer LCL2. The second color filter CF2 may absorb light emitted from the first light emitting elements LD1 and/or the third light emitting elements LD3 to be scattered by the second structure layer LCL2. The third color filter CF3 may absorb light emitted from the first light emitting elements LD1 and/or the second light emitting elements LD2 to be scattered by the second structure layer LCL2. For example, the color filters CF1 to CF3 may prevent visibility deterioration due to scattering, thereby improving visibility.

The light blocking layer LBL may be disposed between the color filters CF1 to CF3. The light blocking layer LBL may include a black coloring agent such as a black dye or a black pigment. For example, the light blocking layer LBL may include carbon black or a metal such as chromium, or any oxide thereof.

The overcoat layer OCL may be disposed over the color filters CF1 to CF3 and the light blocking layer LBL. The overcoat layer OCL may cover unevenness generated in a process of forming the color filters CF1 to CF3 and the light blocking layer LBL, and provide a flat top surface. The overcoat layer OCL may include various materials suitable for protecting lower layers from foreign matters such as dust and moisture. For example, the overcoat layer OCL may include at least one of an inorganic insulating layer and an organic insulating layer. For example, the overcoat layer OCL may include epoxy resin, but the disclosure is not limited thereto.

FIG. 3 is a schematic view illustrating a first structure layer in accordance with an embodiment of the disclosure.

Referring to FIG. 3, the first structure layer LCL1 may control the viewing angle of light emitted from the light emitting elements LD. The light emitting elements LD may emit lights L1 to L3 having various viewing angles. For example, a viewing angle of first light L1 may be smaller than a viewing angle of second light L2, and the viewing angle of the second light L2 may be smaller than a viewing angle of third light L3. For example, the first light L1 may have the smallest viewing angle, and the third light L3 may have the largest viewing angle.

The first light L1 may not be incident into the second pattern layer LRL, and may be transmitted through the first pattern layer LTL. For example, the viewing angle and intensity of the first light L1 may not be changed.

The second light L2 may be incident into the second pattern layer LRL such that at least a portion thereof may be absorbed or reflected. Therefore, the viewing angle and intensity of the second light L2 may be decreased. The third light L3 may be incident into the second pattern layer LRL such that at least a portion thereof is absorbed or reflected. Since the viewing angle of the third light L3 may be greater than the viewing angle of the second light L2, the third light L3 may be incident several times into the second pattern layer LRL, and therefore, a degree to which at least a portion of the third light L3 is absorbed or reflected may be greater than a degree to which at least a portion of the second light L2 is absorbed or reflected. Accordingly, the viewing angle and intensity of the third light L3 may be further decreased.

As such, the viewing angle of light having a relatively large viewing angle among lights emitted from the light emitting elements LD to pass through the first structure layer LCL1 may be decreased.

FIGS. 4 and 5 are schematic views illustrating a second structure layer in accordance with an embodiment of the disclosure.

Referring to FIGS. 4 and 5, the second structure layer LCL2 may increase/decrease the viewing angle of light passing through the first structure layer LCL1 according to whether a voltage is applied.

Referring to FIG. 4, in case OFF that any voltage is not applied to the first electrode E1 and the second electrode E2, the scattering particles SC included in the switching layer LSL may be irregularly arranged to maintain an optical state in which the scattering degree of the scattering particles SC is high. Therefore, light of which viewing angle is decreased while passing through the first structure layer LCL1 may be scattered with a large scattering angle in the switching layer LSL, so that the viewing angle is increased. Accordingly, the display device 1000 may display an image with a wide viewing angle.

Referring to FIG. 5, in case ON that a voltage is applied to the first electrode E1 and the second electrode E2, the scattering particles SC included in the switching layer LSL may be regularly arranged to maintain a state in which the scattering degree of the scattering particles SC is low. Therefore, light of which viewing angle is decreased while passing through the first structure layer LCL1 may be scattered with a small scattering angle in the switching layer LSL, so that the viewing angle is decreased or so that a change in the viewing angle may be insignificant. Accordingly, the display device 1000 may display an image with a narrow viewing angle.

As such, the viewing angle of light passing through the second structure layer LCL2 may be increased/decreased based on the optical state of the second structure layer LCL2 according to whether the voltage is applied.

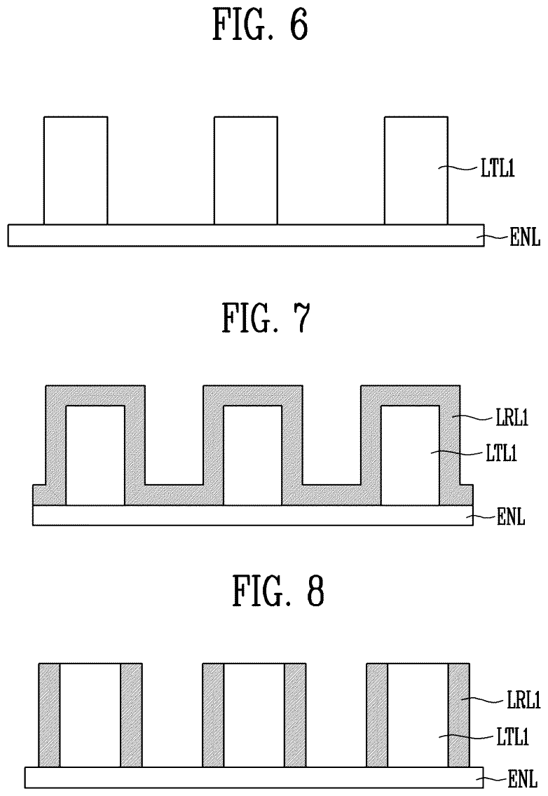

FIGS. 6 to 9 are schematic views illustrating a manufacturing process of the first structure layer in accordance with an embodiment of the disclosure.

Referring to FIG. 6, (1-1)th pattern layers LTL1 spaced apart from each other may be formed on the encapsulation layer ENL. The (1-1)th pattern layers LTL1 may be formed, e.g., through a photo process of applying, exposing, and developing an organic material on the encapsulation layer ENL. In some embodiments, an inorganic material may be deposited on the (1-1)th pattern layers LTL1 and the encapsulation layer ENL through a chemical vapor deposition process after the photo process.

Referring to FIG. 7, a (2-1)th pattern layer LRL1 may be formed over the (1-1)th pattern layers LTL1 and the encapsulation layer ENL. The (2-1)th pattern layer LRL1 may be formed by depositing, e.g., a metal, a metal oxide, or any combination thereof on the (1-1)th pattern layers LTL1 and the encapsulation layer ENL, using a sputtering technique. The (2-1)th pattern layer LRL1 may be formed to cover the (1-1)th pattern layers LTL1 and the encapsulation layer ENL.

Referring to FIG. 8, the (2-1)th pattern layer LRL1 except portions in contact with side surfaces of the (1-1)th pattern layers LTL1 is etched. The (2-1)th pattern layer LRL1 may be etched such that upper surfaces of the (1-1)th pattern layers LTL1 and portions of an upper surface of the encapsulation layer ENL are exposed. In an embodiment, after the etching is completed, the (2-1)th pattern layers LRL1 may have a thickness in a range of about 50 μm to about 100 μm.

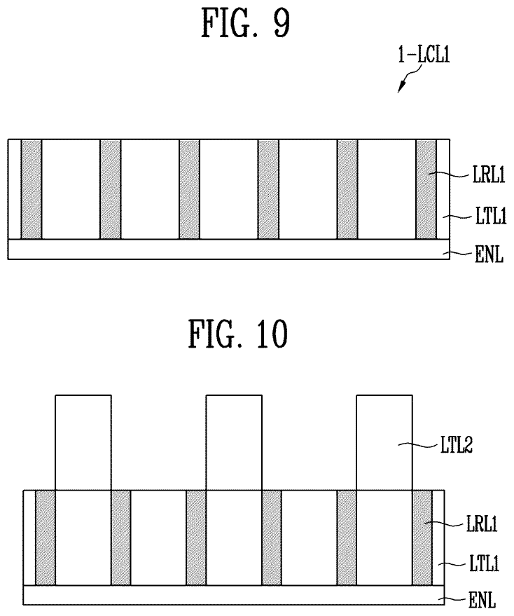

Referring to FIG. 9, (1-1)th pattern layers LTL1 may be formed between the (2-1)th pattern layers LRL1. The (1-1)th pattern layers LTL1 may cover the exposed portions of the encapsulation layer ENL. Accordingly, a first structure layer 1-LCL1 having a single-layer structure (or single-stage structure) may be formed, the single-layer structure including the (1-1)th pattern layers LTL1 and the (2-1)th pattern layers LRL1, which are alternately disposed on the encapsulation layer ENL.

FIGS. 10 to 13 are schematic views illustrating a manufacturing process of the first structure layer in accordance with another embodiment of the disclosure.

Referring to FIG. 10, (1-2)th pattern layers LTL2 spaced apart from each other may be formed on the (1-1)th pattern layers LTL1. The (1-2)th pattern layers LTL2 may be formed, e.g., through a photo process of applying, exposing, and developing an organic material on the (1-1)th pattern layers LTL1.

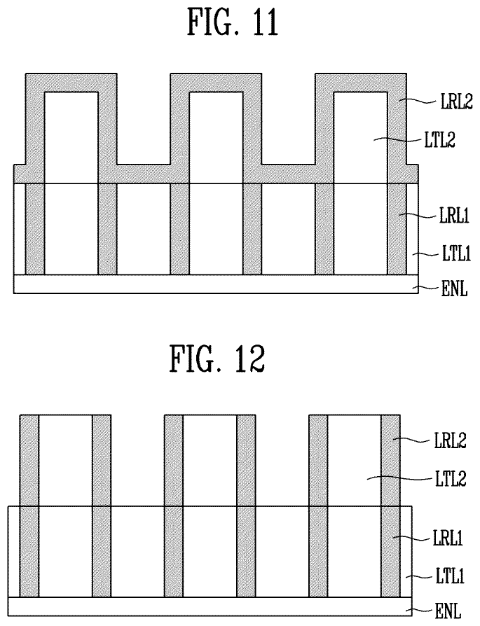

Referring to FIG. 11, a (2-2)th pattern layer LRL2 may be formed over the (1-1)th pattern layers LTL1 and the (2-1)th pattern layers LRL1. The (2-2)th pattern layer LRL2 may be formed by depositing, e.g., a metal, a metal oxide, or any combination thereof on the (1-1)th pattern layers LTL1 and the (2-1)th pattern layers LRL1, using a sputtering technique. The (2-2)th pattern layer LRL2 may be formed to cover or overlap the (1-1)th pattern layers LTL1 and the (2-1)th pattern layers LRL1.

Referring to FIG. 12, the (2-2)th pattern layer LRL2 except portions in contact with side surfaces of the (1-2)th pattern layer LTL2 may be etched. The (2-2)th pattern layer LRL2 may be etched such that upper surfaces of the (1-1)th pattern layers LTL1 and upper surfaces of the (1-2)th pattern layers LTL2 may be exposed. In an embodiment, after the etching is completed, a total thickness of the (2-1)th pattern layer LRL1 and the (2-2)th pattern layer LRL2 may be in a range of about 50 μm to about 100 μm.

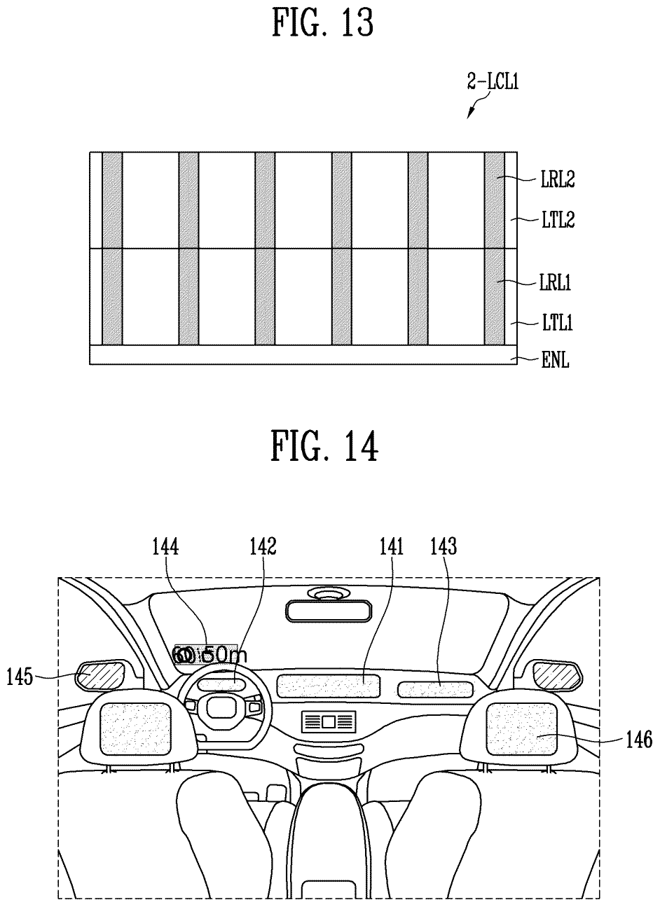

Referring to FIG. 13, (1-2)th pattern layers LTL2 may be formed between the (2-2)th pattern layers LRL2. The (1-2)th pattern layers LTL2 may cover the exposed portions of the (1-1)th pattern layers LTL1. Accordingly, a first structure layer 2-LCL1 having a multi-layer structure may be formed, the multi-layer structure including first pattern layers LTL1 and LTL2 and second pattern layers LRL1 and LRL2, which are alternately disposed on the encapsulation layer ENL. Further, as the above-described processes are repeated, a first structure layer LCL1 (see FIG. 2) having a multi-layer structure with two or more stages may be formed.

FIG. 14 schematically illustrates an example of an electronic device including a display device in accordance with embodiments of the disclosure.

Referring to FIG. 14, the display device in accordance with the above-described embodiments may be applied to an automotive display. In an example, the automotive display may mean an electronic device provided inside and/or outside a vehicle to provide image data.

For example, the display device in accordance with the above-described embodiments may be applied to at least one of an infortainment panel 141, a cluster 142, a co-driver display 143, a head-up display 144, a side mirror display 145, and a rear seat display 146, which may be provided inside and/or outside the vehicle. Accordingly, a screen viewing angle may be controlled in case that the vehicle is driven, thereby helping driver's forward-looking, or a wide viewing angle may be provided instead of a side mirror function, thereby reducing dead zones.

In accordance with the disclosure, there can be provided a display device, a manufacturing method of the display device, and an automotive display including the display device, which can control a viewing angle while not deteriorating visibility.

The above description is an example of technical features of the disclosure, and those skilled in the art to which the disclosure pertains will be able to make various modifications and variations. Thus, the embodiments of the disclosure described above may be implemented separately or in combination with each other.

The embodiments disclosed in the disclosure are intended not to limit the technical spirit of the disclosure but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a display panel including:
light emitting elements; and
an encapsulation layer overlapping the light emitting elements;
a first structure layer disposed on the encapsulation layer, the first structure layer primarily controlling a path of light emitted from the light emitting elements;
a second structure layer disposed on the first structure layer, the second structure layer secondarily controlling the path of the light passing through the first structure layer; and
a color filter layer disposed on the second structure layer.

2. The display device of claim 1, wherein the first structure layer includes:
a first pattern layer allowing the light to be transmitted through the first pattern layer; and
a second pattern layer alternately disposed with the first pattern layer, the second pattern layer absorbing at least a portion of the light.

3. The display device of claim 2, wherein the first pattern layer includes a transparent organic material.

4. The display device of claim 2, wherein the second pattern layer includes at least one of a metal and a metal oxide.

5. The display device of claim 2, wherein the second pattern layer decreases a viewing angle of the light emitted from the light emitting elements.

6. The display device of claim 2, wherein the first pattern layer and the second pattern layer have a same thickness.

7. The display device of claim 2, wherein the second pattern layer has a thickness in a range of about 50 μm to about 100 μm.

8. The display device of claim 2, wherein the first pattern layer and the second pattern layer have a single-layer structure.

9. The display device of claim 2, wherein the first pattern layer and the second pattern layer have a multi-layer structure with two or more stages.

10. The display device of claim 1, wherein the second structure layer includes:
a first electrode disposed on the first structure layer;
a switching layer disposed on the first electrode; and
a second electrode disposed on the switching layer.

11. The display device of claim 10, wherein
the switching layer includes a scattering particle in which a first state and a second state are electrically switchable, and
the second state has a scattering degree lower than a scattering degree of the first state.

12. The display device of claim 11, wherein in case that a voltage is not applied to the first electrode and the second electrode, the scattering particle maintains the first state.

13. The display device of claim 11, wherein in case that a voltage is applied to the first electrode and the second electrode, the scattering particle maintains the second state.

14. The display device of claim 11, wherein in case that the scattering particle is in the first state, the switching layer increases a viewing angle of the light passing through the first structure layer.

15. The display device of claim 11, wherein in case that the scattering particle is in the second state, the switching layer decreases a viewing angle of the light passing through the first structure layer.

16. A method of manufacturing a display device, the method comprising:
preparing a display panel including light emitting elements and an encapsulation layer overlapping the light emitting elements;
forming a first structure layer on the encapsulation layer;
forming a second structure layer on the first structure layer; and
forming a color filter layer on the second structure layer.

17. The method of claim 16, wherein the forming of the first structure layer includes:
forming first pattern layers spaced apart from each other on the encapsulation layer;
forming a second pattern layer overlapping the first pattern layers and the encapsulation layer;
etching the second pattern layer except portions in contact with side surfaces of the first pattern layers; and
forming the first pattern layers between the second pattern layers.

18. The method of claim 17, wherein the first pattern layers and the second pattern layer are formed in a single-layer structure or a multi-layer structure with two or more stages.

19. The method of claim 17, wherein the second pattern layer is formed with a thickness in a range of about 50 μm to about 100 μm.

20. An automotive display comprising the display device of claim 1.
